(19) United States
(12) Patent Application Publication
(10) Pub. No.: US 2026/0293570 A1
(43) Pub. Date: Sep. 24, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Takashi IZUTA, Kyoto (JP); Ryunosuke UETA, Kyoto (JP)

(21) Appl. No.: 19/564,031

(22) Filed: Mar. 11, 2026

(30) Foreign Application Priority Data
Mar. 19, 2025 (JP) 2025-045880

(51) Int. Cl. H10P 72/00

(52) U.S. Cl. CPC H10P 72/0408; H10P 72/0416

(57) ABSTRACT

A yield of a product is improved. The substrate processing apparatus includes a control section, and in cooperation with a memory, the control section carries out control to (i) immerse a substrate in a processing liquid stored in a processing tank, (ii) make an atmosphere of an organic solvent gas in a chamber, (iii) supply the organic solvent gas toward an area including a contact position between a lifter and the substrate in a state in which the substrate is pulled out of the processing tank, and (iv) supply the organic solvent gas toward the area including the contact position between the lifter and the substrate with the chamber in a depressurized state and continue the supply for a predetermined time period.

### DESCRIPTION

This Nonprovisional application claims priority under 35 U.S.C. §119 on Patent Application No. 2025-045880 filed in Japan on Mar. 19, 2025, the entire contents of which are hereby incorporated by reference.

### Technical Field

The present disclosure relates to a substrate processing apparatus and a substrate processing method.

### Background Art

A batch-type substrate processing apparatus for simultaneously processing a plurality of substrates W has been known. For example, a substrate processing apparatus disclosed in Patent Literature 1 carries out a cleaning process in which each substrate retained by a lifter is immersed in pure water stored in a processing tank to be cleaned. After carrying out the cleaning process, the substrate processing apparatus carries out a drying process of drying a substrate by a drying gas.

### Citation List

### Patent Literature

### Patent Literature 1

Japanese Patent Application Publication Tokukai No. 2007-273819

### SUMMARY OF INVENTION

### Technical Problem

It has been known that, on a substrate that has undergone a drying process, peculiar particles adhere to the vicinity of a portion supported by a support plate of the lifter. With recent advances in the miniaturization of semiconductor devices, the edge exclusion width has been decreasing. Under these circumstances, there has been a need to reduce the occurrence of the peculiar particles adhering to the vicinity of the portion of the substrate supported by the support plate, because there is a risk that these particles directly affect yields of products.

It is an object of an aspect of the present disclosure to improve a yield of a product.

### Solution to Problem

In order to solve the foregoing problem, a substrate processing apparatus in accordance with the present disclosure is a substrate processing apparatus configured to carry out a predetermined process on a substrate, the substrate processing apparatus including: a processing tank storing a processing liquid; a chamber accommodating the processing tank; a lifter retaining the substrate; a movement mechanism configured to raise and lower the lifter between a first position where the substrate is immersed in the processing liquid inside the processing tank and a second position where the substrate is located outside the processing tank; a processing liquid nozzle configured to supply a processing liquid to the processing tank; a gas nozzle configured to supply an inert gas or organic solvent gas into the chamber; a control section configured to control an operation by the movement mechanism and control a supply operation for a processing liquid by the processing liquid nozzle, a supply operation for the inert gas by the gas nozzle, and a supply operation for the organic solvent gas by the gas nozzle; and a memory storing information indicating a control operation of the control section, wherein in cooperation with the memory, the control section carries out control to (i) immerse the substrate in the processing liquid stored in the processing tank, (ii) make an atmosphere of the organic solvent gas in the chamber, (iii) supply the organic solvent gas toward an area including a contact position between the lifter and the substrate in a state in which the substrate is pulled out of the processing tank, and (iv) supply the organic solvent gas toward the area including the contact position between the lifter and the substrate with the chamber in a depressurized state and continue the supply for a predetermined time period.

In order to solve the foregoing problem, a substrate processing method in accordance with the present disclosure is a substrate processing method for a substrate processing apparatus configured to carry out a predetermined process on a substrate, the substrate processing apparatus including a processing tank storing a processing liquid, a chamber accommodating the processing tank, a lifter retaining the substrate, a movement mechanism configured to raise and lower the lifter between a first position where the substrate is immersed in the processing liquid inside the processing tank and a second position where the substrate is located outside the processing tank, a processing liquid nozzle configured to supply a processing liquid to the processing tank, and a gas nozzle configured to supply an inert gas or organic solvent gas into the chamber, the substrate processing method comprising: (i) immersing the substrate in the processing liquid stored in the processing tank; (ii) making an atmosphere of the organic solvent gas in the chamber; (iii) supplying the organic solvent gas toward an area including a contact position between the lifter and the substrate in a state in which the substrate is pulled out of the processing tank; and (iv) supplying the organic solvent gas toward the area including the contact position between the lifter and the substrate with the chamber in a depressurized state and continuing the supplying for a predetermined time period.

### Advantageous Effects of Invention

According to an aspect of the present disclosure, it is possible to improve a yield of a product.

### BRIEF DESCRIPTION OF DRAWINGS

FIG. 1 is a view schematically illustrating one example of a schematic configuration of a substrate processing apparatus.

FIG. 2 is a block diagram illustrating a configuration of the substrate processing apparatus.

FIG. 3 is a perspective view schematically illustrating a configuration of a lifter.

FIG. 4 is a front view schematically illustrating the lifter as viewed from the front.

FIG. 5 is a view illustrating one example of a substrate processing method carried out by a substrate processing apparatus.

FIG. 6 is a view schematically illustrating one cause of adhesion of peculiar particles to a substrate.

### DESCRIPTION OF EMBODIMENTS

### Embodiment 1

The following description will discuss an embodiment of the present disclosure in detail.

### Overview of substrate processing apparatus

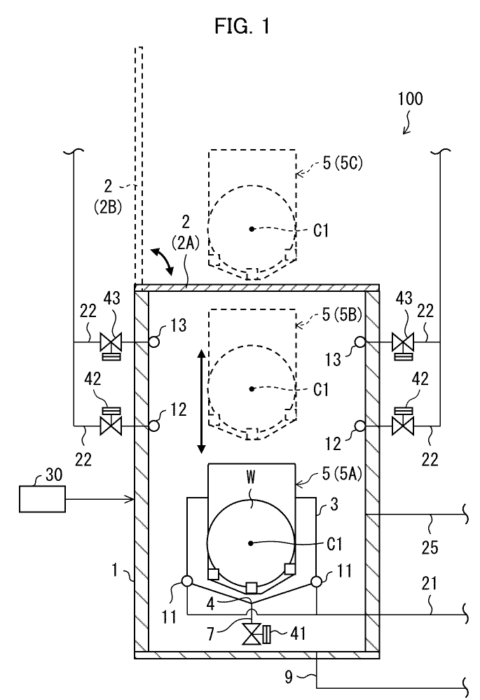

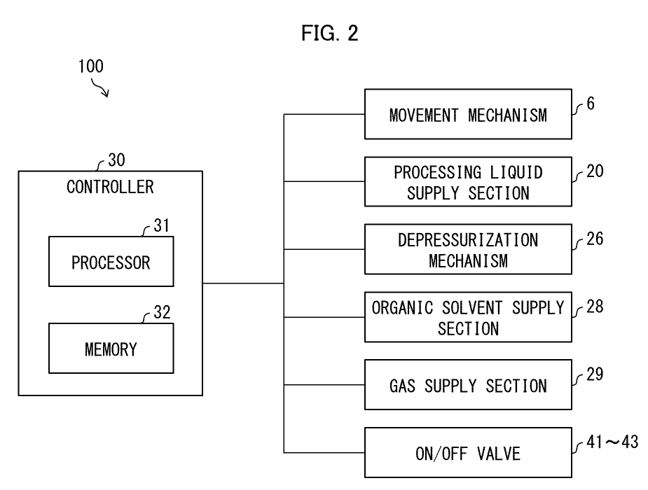

With reference to FIGS. 1 and 2, the following will describe an example of a schematic configuration of a substrate processing apparatus 100. FIG. 1 is a view schematically illustrating one example of a schematic configuration of the substrate processing apparatus 100. FIG. 2 is a block diagram illustrating a configuration of the substrate processing apparatus 100. The substrate processing apparatus 100 is an apparatus configured to carry out a predetermined process on a substrate. The substrate processing apparatus 100 carries out various processes on a substrate W with use of a processing liquid and a processing gas. The substrate W is, for example, a semiconductor substrate, such as a silicon wafer. The substrate processing apparatus 100 includes a chamber 1, a processing tank 3, a lifter 5, a movement mechanism 6 (see FIG. 2), processing liquid nozzles 11, and gas nozzles 12 and 13.

As illustrated in FIG. 1, the chamber 1 accommodates the processing tank 3. An opening/closing lid 2 that opens and closes an opening formed in an upper portion of the chamber 1 is provided in an upper portion of the chamber 1. The opening/closing lid 2 is movable between a closing position 2A where the opening formed in the upper portion of the chamber 1 is closed and an opening position 2B where the opening is opened.

The processing tank 3 stores a processing liquid. The processing liquid is not particularly limited, and examples thereof include a chemical liquid and pure water. Examples of the pure water include ultrapure water (such as de-ionized water (DIW)). Examples of the chemical liquid include an ammonia-hydrogen peroxide mixture (SC-1), a hydrochloric acid-hydrogen peroxide mixture (SC-2), hydrogen fluoride (HF), isopropyl alcohol (IPA), and tetramethylammonium hydroxide (TMAH).

The processing tank 3 is provided with processing liquid nozzles 11 connected to a processing liquid supply pipe 21. Each of the processing liquid nozzles 11 supplies a processing liquid to the processing tank 3. More specifically, the processing liquid is supplied to the processing liquid nozzle 11 from a processing liquid supply section 20 (see FIG. 2) via the processing liquid supply pipe 21. In the processing liquid stored in the processing tank 3, the substrate W raised and lowered by the lifter 5 is to be immersed.

At a lower portion of the processing tank 3, a drainage port 4 for draining the processing liquid inside the processing tank 3 to the outside of the processing tank 3 is formed. The drainage port 4 is connected to a drainage pipe 7 provided with an on/off valve 41. The processing liquid inside the processing tank 3 is drained to the bottom portion of the chamber 1 via the drainage pipe 7 when the on/off valve 41 is in an opened state, and is not drained to the bottom portion of the chamber 1 via the drainage pipe 7 when the on/off valve 41 is in a closed state. A liquid drainage pipe 9 is connected to the bottom portion of the chamber 1. The liquid accumulated at a bottom portion of the chamber 1 is drained to the outside of the chamber 1 via the liquid drainage pipe 9 when an unillustrated on/off valve is in an opened state.

The lifter 5 retains the substrate W. More specifically, the lifter 5 supports an outer peripheral edge portion of the substrate W and retains a plurality of substrates W so that the substrates W are arranged in a normal direction of a substrate surface and are each in an upright orientation. The lifter 5 is raised and lowered by the movement mechanism 6 described later with respect to the chamber 1.

The lifter 5 is movable to a first position 5A, a second position 5B, and a third position 5C. The first position 5A is a position where the substrate W supported by the lifter 5 is immersed in the processing liquid inside the processing tank 3. The second position 5B is a position where the substrate W supported by the lifter 5 is located outside the processing tank 3. Further, in the present embodiment, the second position 5B is a position where the substrate W supported by the lifter 5 is placed inside the chamber 1. The second position 5B is located inside the chamber 1 and above the first position 5A. The third position 5C is a position where the substrate W supported by the lifter 5 is located outside the chamber 1.

An exhaust pipe 25 is connected to the chamber 1. The exhaust pipe 25 is connected to a depressurization mechanism 26 (see FIG. 2) that reduces the pressure inside the chamber 1.

The chamber 1 is provided with gas nozzles 12 and gas nozzles 13. The gas nozzles 12 and the gas nozzles 13 are nozzles configured to supply organic solvent gas or inert gas into the chamber 1. That is, the gas nozzles 12 and the gas nozzles 13 each have both a function as a gas nozzle for supplying inert gas into the chamber 1 and a function as a gas nozzle for supplying organic solvent gas into the chamber 1. The gas nozzles 12 and the gas nozzles 13 are each connected to a gas supply pipe 22.

The gas nozzles 12 and the gas nozzles 13 are each provided in an upper portion of the chamber 1. In the present embodiment, the gas nozzles 12 supply organic solvent gas or inert gas toward an area including a contact position between the lifter 5 located in the second position 5B and the substrate W. The gas nozzles 12 are disposed in a position lower than the height of the center C1 of the substrate W retained by the lifter 5 located in the second position 5B.

Although details will be described later, the substrate W is retained by the lifter 5 by being placed on side retaining arms 60 and a center retaining arm 70 of the lifter 5. That is, the contact position between the lifter 5 and the substrate W is located, in an outer edge portion of the substrate W, below the height of the center C1 of the substrate W. On the other hand, as described above, the gas nozzles 12 are disposed in a position lower than the height of the center C1 of the substrate W retained by the lifter 5 located in the second position 5B. In other words, the substrate surface of the substrate W does not exist between the contact position between the lifter 5 and the substrate W and the gas nozzles 12. As a result, the organic solvent gas or inert gas discharged from the gas nozzles 12 directly reaches the contact position between the lifter 5 and the substrate W without passing through the substrate surface of the substrate W. Therefore, the organic solvent gas or the inert gas can be efficiently sprayed to the contact position between the lifter 5 and the substrate W.

Note that it is preferable that the gas nozzles 12 be disposed in a position higher than the height of the center retaining arm 70 of the lifter 5 located in the second position 5B. In this case, the gas nozzles 12 are disposed in a position closer to the side retaining arms 60, and thus can more efficiently spray the organic solvent gas or inert gas to the contact position between the lifter 5 and the substrate W.

The gas nozzles 13 are disposed above the gas nozzles 12. The gas nozzles 13 are disposed, in the vertical direction, above the upper end of the substrate W retained by the lifter 5 located in the second position 5B. In the present embodiment, the gas nozzles 13 discharge the organic solvent gas or inert gas toward an upper portion of the chamber 1, that is, in a direction in which the opening/closing lid 2 is located. That is, the gas nozzles 13 are provided in order to supply the organic solvent gas or inert gas throughout the inside of the chamber 1.

The gas supply pipe 22 is provided with on/off valves 42 and on/off valves 43. More specifically, the on/off valves 42 are provided in the gas supply pipe 22 that is connected to the gas nozzles 12. Organic solvent gas or inert gas is discharged into the chamber 1 from the gas nozzles 12 when the on/off valves 42 are in an opened state, and the organic solvent gas or inert gas is not discharged into the chamber 1 from the gas nozzles 12 when the on/off valves 42 are in a closed state. The on/off valves 43 are provided in the gas supply pipe 22 that is connected to the gas nozzles 13. Organic solvent gas or inert gas is discharged into the chamber 1 from the gas nozzles 13 when the on/off valves 43 are in an opened state, and the organic solvent gas or inert gas is not discharged into the chamber 1 from the gas nozzles 13 when the on/off valves 43 are in a closed state.

As illustrated in FIG. 2, the substrate processing apparatus 100 includes the movement mechanism 6 and a controller 30. In the present embodiment, the substrate processing apparatus 100 may further include a processing liquid supply section 20, the depressurization mechanism 26, an organic solvent supply section 28, and a gas supply section 29.

The movement mechanism 6 is a mechanism configured to raise and lower the lifter 5 between the first position 5A and the second position 5B. Further, in the present embodiment, the movement mechanism 6 raises and lowers the lifter 5 between the second position 5B and the third position 5C and between the third position 5C and the first position 5A. The movement mechanism 6 includes an unillustrated driving motor, and raises and lowers the lifter 5 by a driving force from the driving motor.

The processing liquid supply section 20 supplies the processing liquid to the processing liquid nozzles 11. When an unillustrated driving section is driven, the processing liquid supply section 20 supplies the processing liquid from an unillustrated tank storing the processing liquid, to the processing liquid supply pipe 21. The processing liquid supply pipe 21 is provided with an unillustrated on/off valve, and when the on/off valve is in an opened state, the processing liquid supplied from the processing liquid supply pipe 21 is discharged from the processing liquid nozzles 11.

The depressurization mechanism 26 reduces the pressure inside the chamber 1. The depressurization mechanism 26 includes, for example, an unillustrated exhaust pump and an unillustrated exhaust valve. For example, the exhaust valve is provided to the exhaust pipe 25. When an exhaust pump is driven with the exhaust valve in an opened state, gas in the chamber 1 is exhausted to the outside of the chamber 1 via the exhaust pipe 25. The depressurization mechanism 26 reduces the pressure in the chamber 1 by exhausting the gas in the chamber 1 via the exhaust pipe 25.

The organic solvent supply section 28 supplies organic solvent vapor as organic solvent gas into the chamber 1 via the gas supply pipe 22 from the gas nozzles 12 or the gas nozzles 13. The organic solvent supply section 28 includes, for example, an unillustrated organic solvent tank, an unillustrated organic solvent vapor supply pipe, and an unillustrated vapor on/off valve. The organic solvent tank is a tank that stores an organic solvent and generates vapor of the organic solvent. The organic solvent vapor supply pipe is connected to the gas supply pipe 22. The vapor on/off valve is provided to the organic solvent vapor supply pipe. When the vapor on/off valve is in an opened state, the organic solvent vapor is supplied to the gas supply pipe 22 from the organic solvent vapor supply pipe. Examples of the organic solvent supplied from the organic solvent supply section 28 include a liquid containing at least one of isopropyl alcohol (IPA), hydrofluoroether (HFE), methanol, ethanol, acetone, and Trans-1,2-dichloroethylene.

For example, reduction of the pressure inside the chamber 1 by the depressurization mechanism 26 when the on/off valves 42 and/or the on/off valves 43 are in an opened state allows the organic solvent vapor generated in the organic solvent tank to be supplied to the organic solvent vapor supply pipe and the gas supply pipe 22. The gas nozzles 12 and/or the gas nozzles 13 discharge, into the chamber 1, the organic solvent vapor supplied via the gas supply pipe 22.

The gas supply section 29 supplies inert gas into the chamber 1 via the gas supply pipe 22 from the gas nozzles 12 or the gas nozzles 13. For example, when an unillustrated driving section is driven, the gas supply section 29 supplies inert gas to the gas supply pipe 22 from an unillustrated inert gas tank storing the inert gas. The gas supply section 29 may include a gas on/off valve provided to an unillustrated inert gas supply pipe connected to the gas supply pipe 22. When the gas on/off valve is in an opened state, the inert gas is supplied to the gas supply pipe 22 from the inert gas supply pipe. Examples of the inert gas supplied from the gas supply section 29 include nitrogen gas (N₂) and argon gas (Ar).

For example, driving of the gas supply section 29 when the on/off valves 42 and/or the on/off valves 43 are in an opened state allows the inert gas stored in the inert gas tank to be supplied to the inert gas supply pipe and the gas supply pipe 22. The gas nozzles 12 and/or the gas nozzles 13 discharge the inert gas supplied via the gas supply pipe 22, into the chamber 1.

The controller 30 controls the sections included in the substrate processing apparatus 100. The controller 30 includes a processor 31 and a memory 32. The processor 31 is one example of a control section.

The processor 31 carries out various processes in cooperation with the memory 32. The memory 32 stores information indicating control operations of the processor 31. For example, the processor 31 carries out various processes described later in accordance with a program stored in the memory 32 and serving as information indicating the control operations of the processor 31. The processor 31 includes, for example, a central processing unit (CPU), a digital signal processor (DSP), a graphic processing unit (GPU), and a micro processing unit (MPU). The memory 32 includes, for example, a read only memory (ROM), a random access memory (RAM), a flash memory, and a hard disk drive (HDD).

The processor 31 controls the operations by the movement mechanism 6. Further, the processor 31 controls a supply operation for the processing liquid by the processing liquid nozzle 11, a supply operation for the inert gas by the gas nozzles 12 and 13, and a supply operation for the organic solvent gas by the gas nozzles 12 and 13. More specifically, when controlling the supply operation for the processing liquid by the processing liquid nozzle 11, the processor 31 controls the processing liquid supply section 20. When controlling the supply operation for the inert gas by the gas nozzles 12 and 13, the processor 31 controls the depressurization mechanism 26, the gas supply section 29, and the on/off valves 42 and 43. When controlling the supply operation for the organic solvent gas by the gas nozzles 12 and 13, the processor 31 controls at least one of the depressurization mechanism 26, the organic solvent supply section 28, and the on/off valves 42 and 43. In the present embodiment, the processor 31 further controls the on/off valve 41.

### Configuration of lifter

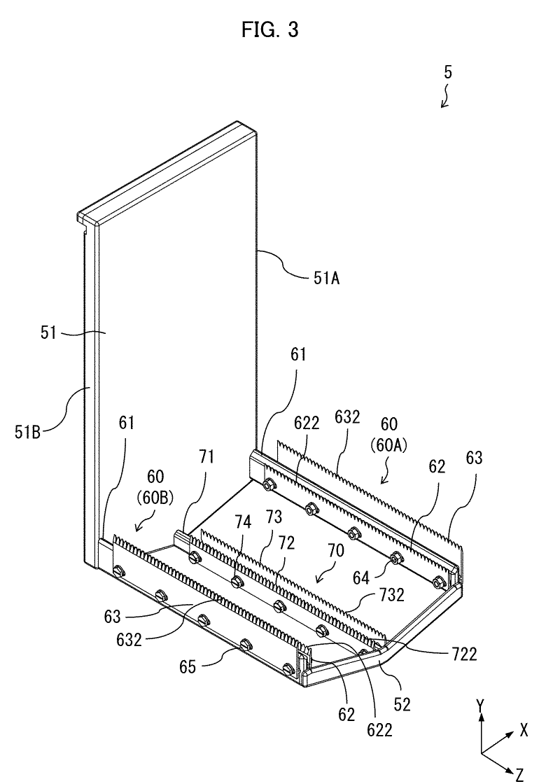

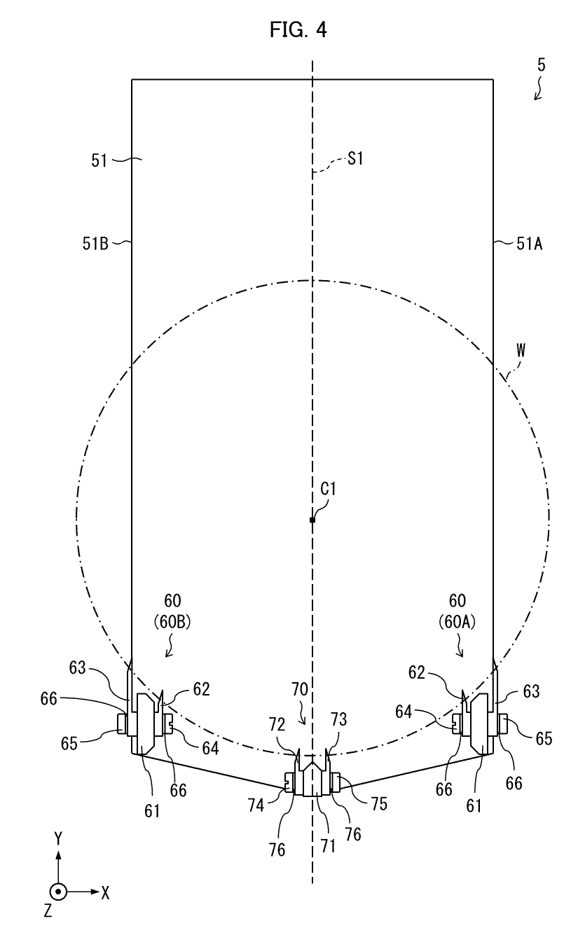

Next, with reference to FIGS. 3 and 4, the following will describe a configuration of the lifter 5 in detail. FIG. 3 is a perspective view schematically illustrating a configuration of the lifter 5. FIG. 4 is a front view schematically illustrating the lifter 5 as viewed from the front. Note that, in the following description, an XYZ coordinate system is defined as illustrated in, for example, FIG. 3. The X-axis direction is a horizontal direction. The Y-axis direction is the vertical direction. A Y-axis positive direction is an upward direction, and a Y-axis negative direction is a downward direction. The Z-axis direction is a horizontal direction, and is orthogonal to the X-axis direction. The XZ plane is a horizontal plane.

As illustrated in FIGS. 3 and 4, the lifter 5 is provided with at least a fixation arm 51 and the side retaining arms 60. In the present embodiment, the lifter 5 further includes a coupling arm 52 and the center retaining arm 70.

The fixation arm 51 retains the side retaining arms 60. In the present embodiment, the fixation arm 51 further retains the center retaining arm 70. The fixation arm 51 is a rectangular member extending in the Y-axis direction. More specifically, the fixation arm 51 is a plate-shaped member with its lengthwise direction extending in the Y-axis direction and with its widthwise direction extending in the X-axis direction. The thickness direction of the fixation arm 51 is a Z-axis direction. Driving of the movement mechanism 6 causes the fixation arm 51 to move in an up-and-down direction. In accordance with movement of the fixation arm 51 in an up-and-down direction, the side retaining arms 60 and the center retaining arm 70 that are retained by the fixation arm 51 move in the up-and-down direction.

Here, in FIG. 4, an imaginary plane S1 is illustrated. In addition, in FIG. 4, an outer peripheral edge portion of the substrate W retained by the lifter 5 is illustrated by a dotted-and-dashed line. The plane S1 is a plane with a normal direction thereof extending in a horizontal direction, the plane including a line crossing the center C1. The plane S1 is located in a center position of the fixation arm 51 in the X-axis direction. In the present embodiment, the normal direction of the plane S1 is the X-axis direction, and the plane S1 is a YZ plane. Of both the end portions of the fixation arm 51 in the X-axis direction, one end portion is referred to as a first end portion 51A. Of both the end portions of the fixation arm 51 in the X-axis direction, the end portion located opposite from the first end portion 51A is referred to as a second end portion 51B. In the present embodiment, the plane S1 is located in a center position between the first end portion 51A and the second end portion 51B in the X-axis direction.

The coupling arm 52 is a member coupling the side retaining arms 60 and the center retaining arm 70. The coupling arm 52 is a member extending in the X-axis direction, that is, with its lengthwise direction extending in the X-axis direction. The coupling arm 52 has a shape such that its center portion in the X-axis direction is recessed. The coupling arm 52 is a member having a V shape when viewed from the Z-axis direction. In the coupling arm 52, a position corresponding to the plane S1 constitutes the lowermost position.

The side retaining arms 60 retain the substrate W. The side retaining arms 60 include a first side retaining arm 60A and a second side retaining arm 60B. With respect to the plane S1, the first side retaining arm 60A is disposed on one side of the plane S1, and the second side retaining arm 60B is disposed on the other side of the plane S1. That is, in the X-axis direction, the first side retaining arm 60A is located on a first end portion 51A side relative to the plane S1, and the second side retaining arm 60B is located on a second end portion 51B side relative to the plane S1.

In the present embodiment, the first side retaining arm 60A is provided at the first end portion 51A of the fixation arm 51, and the second side retaining arm 60B is provided at the second end portion 51B of the fixation arm 51. In the X-axis direction, the first side retaining arm 60A is located on a first end portion 51A side with respect to the center retaining arm 70, and the second side retaining arm 60B is located on a second end portion 51B side with respect to the center retaining arm 70. Note that in the present specification, in a case where the descriptions are given without distinguishing between the first side retaining arm 60A and the second side retaining arm 60B, they are each referred to simply as "side retaining arm 60".

As illustrated in FIGS. 3 and 4, the side retaining arm 60 includes a retaining body 61, an inner support plate 62, an outer support plate 63, bolts 64, and nuts 65.

As illustrated in FIG. 3, the retaining body 61 is a bar-shaped member with its lengthwise direction extending in the Z-axis direction. One end portion of the retaining body 61 in the Z-axis direction is fixed to a lower portion of the fixation arm 51, and the other end portion of the retaining body 61 in the Z-axis direction is fixed to the coupling arm 52. In the present embodiment, the retaining body 61 of the first side retaining arm 60A is located adjacent to the first end portion 51A of the fixation arm 51 and is fixed to a lower portion of the fixation arm 51. Further, the retaining body 61 of the second side retaining arm 60B is located adjacent to the second end portion 51B of the fixation arm 51 and is fixed to a lower portion of the fixation arm 51.

The retaining body 61 has a side surface on which fixation holes (unillustrated) are formed. Into the fixation holes of the retaining body 61, the bolts 64 are inserted. As illustrated in FIG. 4, the retaining body 61 is located, in the X-axis direction, between the inner support plate 62 and the outer support plate 63.

The inner support plate 62 is disposed on a side surface of the retaining body 61 which is closer to the plane S1. That is, the inner support plate 62 is located, in the X-axis direction, on the plane S1 side relative to the retaining body 61. The inner support plate 62 is fixed to the retaining body 61 by the bolts 64 and the nuts 65 while being spaced apart from the fixation arm 51 and the coupling arm 52. The inner support plate 62 has a side surface on which fixation holes (unillustrated) are formed. Into the fixation holes of the inner support plate 62, the bolts 64 are inserted. As illustrated in FIG. 3, the end portion of the inner support plate 62 in the Y-axis positive direction is provided with a groove portion 622 composed of a plurality of grooves arranged in the Z-axis direction. The groove portion 622 has a comb shape. The substrate W is fitted with each groove of the groove portion 622.

As illustrated in FIG. 4, the outer support plate 63 is disposed on a side surface of the retaining body 61 which is farther from the plane S1. That is, the retaining body 61 is located, in the X-axis direction, on the plane S1 side relative to the outer support plate 63. The outer support plate 63 is fixed to the retaining body 61 by the bolts 64 and the nuts 65 while being spaced apart from the fixation arm 51 and the coupling arm 52. The outer support plate 63 has a side surface on which fixation holes (unillustrated) are formed. Into the fixation holes of the outer support plate 63, the bolts 64 are inserted. As illustrated in FIG. 3, the end portion of the outer support plate 63 in the Y-axis positive direction is provided with a groove portion 632 composed of a plurality of grooves arranged in the Z-axis direction. The groove portion 632 has a comb shape. The substrate W is fitted with each groove of the groove portion 632.

As illustrated in FIG. 4, the outer support plate 63 is longer in the Y-axis direction than the inner support plate 62. The end portion of the outer support plate 63 on a Y-axis positive direction side is located, in a Y-axis direction, on the Y-axis positive direction side relative to the end portion of the inner support plate 62 on the Y-axis positive direction side. That is, the groove portion 632 of the outer support plate 63 is located above the groove portion 622 of the inner support plate 62 in the Y-axis direction.

The bolts 64 and the nuts 65 are members fixing the retaining body 61, the inner support plate 62, and the outer support plate 63. That is, the inner support plate 62 and the outer support plate 63 are each fixed to the retaining body 61 by the bolts 64 and the nuts 65. By tightening the nuts 65 onto the bolts 64, the inner support plate 62 and the outer support plate 63 are fixed to the retaining body 61. In the X-axis direction, the head portions of the bolts 64 are located on an inner support plate 62 side with respect to the retaining body 61, and the nuts 65 are located on an outer support plate 63 side with respect to the retaining body 61. Note that in the X-axis direction, the head portions of the bolts 64 may be located on an outer support plate 63 side with respect to the retaining body 61, and the nuts 65 may be located on an inner support plate 62 side with respect to the retaining body 61.

The side retaining arms 60 may have washers 66. The washers 66 may be disposed between the inner support plate 62 and the head portions of the bolts 64. The washers 66 may be disposed between the outer support plate 63 and the nuts 65.

As illustrated in FIG. 4, the center retaining arm 70 retains, in a position including the plane S1, the outer peripheral edge portions at lowermost edges of the substrates W retained by the lifter 5. In the present embodiment, the center retaining arm 70 is located, in the X-axis direction, at a center position between the first end portion 51A and the second end portion 51B of the fixation arm 51. The center retaining arm 70 includes a center retaining body 71, a first center support plate 72, a second center support plate 73, center bolts 74, and center nuts 75.

As illustrated in FIG. 3, the center retaining body 71 is a bar-shaped member with its lengthwise direction extending in the Z-axis direction. One end portion of the center retaining body 71 in the Z-axis direction is fixed to a lower portion of the fixation arm 51, and the other end portion of the center retaining body 71 in the Z-axis direction is fixed to the coupling arm 52. The center retaining body 71 has a side surface on which fixation holes (unillustrated) are formed. Into the fixation holes of the center retaining body 71, the center bolts 74 are inserted. As illustrated in FIG. 4, the center retaining body 71 is located, in the X-axis direction, between the first center support plate 72 and the second center support plate 73. That is, the center retaining body 71 is located in a position overlapping the plane S1.

The first center support plate 72 is disposed on one side surface of the center retaining body 71. In the present embodiment, the first center support plate 72 is located, in the X-axis direction, on a side toward the second end portion 51B of the fixation arm 51 relative to the center retaining body 71. The first center support plate 72 has a side surface on which fixation holes (unillustrated) are formed. Into the fixation holes of the first center support plate 72, the center bolts 74 are inserted. The first center support plate 72 is fixed to the center retaining body 71 by the center bolts 74 and the center nuts 75 while being spaced apart from the fixation arm 51 and the coupling arm 52.

The second center support plate 73 is disposed on the other side surface of the center retaining body 71. In the present embodiment, the second center support plate 73 is located, in the X-axis direction, on a side toward the first end portion 51A of the fixation arm 51 relative to the center retaining body 71. The second center support plate 73 has a side surface on which fixation holes (unillustrated) are formed. Into the fixation holes of the second center support plate 73, the center bolts 74 are inserted. The second center support plate 73 is fixed to the center retaining body 71 by the center bolts 74 and the center nuts 75 while being spaced apart from the fixation arm 51 and the coupling arm 52.

The groove portions 722 and 732 each of which is composed of a plurality of grooves arranged in the Z-axis direction are formed at respective end portions of the first center support plate 72 and the second center support plate 73 in the Y-axis positive direction. The groove portion 722 and the groove portion 732 each have a comb shape. The substrate W is fitted with each groove of the groove portion 722 and the groove portion 732. The first center support plate 72 and the second center support plate 73 have substantially the same length in the Y-axis direction. Therefore, in the Y-axis direction, the end portion of the first center support plate 72 on the Y-axis positive direction side and the end portion of the second center support plate 73 on the Y-axis positive direction side are located in substantially the same position. That is, in the Y-axis direction, the groove portion 722 of the first center support plate 72 and the groove portion 732 of the second center support plate 73 are located in substantially the same position.

The center bolts 74 and the center nuts 75 are members fixing the center retaining body 71, the first center support plate 72, and the second center support plate 73. That is, the first center support plate 72 and the second center support plate 73 are each attached to the center retaining body 71 by the center bolts 74 and the center nuts 75. By tightening the center nuts 75 onto the center bolts 74, the first center support plate 72 and the second center support plate 73 are fixed to the center retaining body 71. In the X-axis direction, the head portions of the center bolts 74 are located on a second end portion 51B side with respect to the center retaining body 71, and the center nuts 75 are disposed on a side toward the first end portion 51A of the fixation arm 51 with respect to the center retaining body 71. Note that in the X-axis direction, the head portions of the center bolts 74 may be located on the first end portion 51A side with respect to the center retaining body 71, and the center nuts 75 may be disposed on the side toward the second end portion 51B of the fixation arm 51 with respect to the center retaining body 71.

The center retaining arm 70 may have center washers 76. The center washers 76 may be disposed between the first center support plate 72 and the head portions of the center bolts 74 and/or between the second center support plate 73 and the center nuts 75.

### Substrate processing method

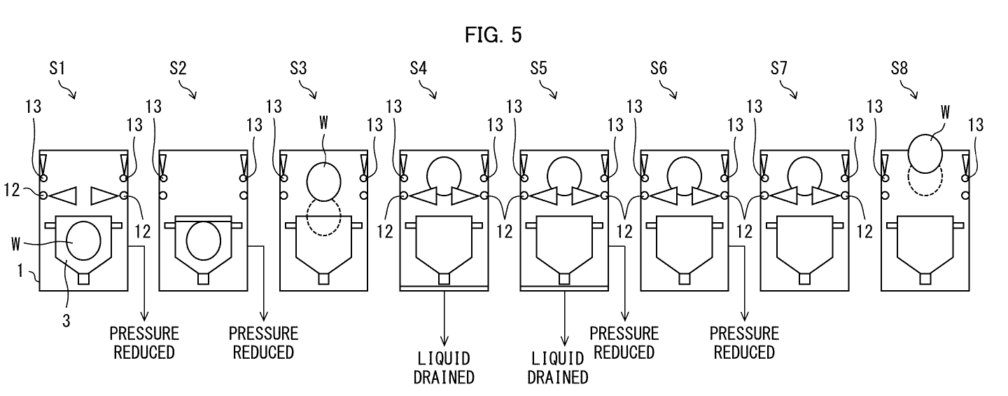

Next, with reference to FIG. 5, the following will describe one example of a substrate processing method carried out by the substrate processing apparatus 100. FIG. 5 is a view illustrating one example of the substrate processing method carried out by the substrate processing apparatus 100. Note that, in FIG. 5, for clarity of the drawing, only the main parts of the configuration of the substrate processing apparatus 100 are illustrated, and illustration of the other components is omitted. Furthermore, in FIG. 5, for clarity of the drawing, among the illustrated main parts of the substrate processing apparatus 100, some components may be assigned reference numerals, and reference numerals for the other components may be omitted.

As illustrated in FIG. 5, a process of immersing the substrate W in the processing liquid stored in the processing tank 3 is carried out in the step S1. In the step S1, the processor 31 controls the on/off valve 41 to a closed state, and drives the processing liquid supply section 20 for a predetermined time period. The processing liquid nozzles 11 thus discharge, into the processing tank 3, the processing liquid supplied to the processing liquid supply pipe 21, thereby storing the processing liquid in the processing tank 3. In the step S1, after the processing liquid has been stored in the processing tank 3, the processor 31 controls the movement mechanism 6 to cause the lifter 5 retaining the substrate W to move to the first position 5A. The substrate W is thus immersed in the processing liquid inside the processing tank 3.

In the step S1, after immersing the substrate W in the processing liquid, the processor 31 supplies inert gas into the chamber 1 via the gas nozzles 12 and the gas nozzles 13. More specifically, in the step S1, the processor 31 controls the on/off valves 42 and the on/off valves 43 to an opened state, and drives the gas supply section 29 for a predetermined time period. The gas nozzles 12 and the gas nozzles 13 discharge, into the chamber 1, the inert gas supplied to the gas supply pipe 22, thereby filling the chamber 1 with the inert gas. In the step S1, after the chamber 1 has been filled with the inert gas, the processor 31 drives the depressurization mechanism 26 for a predetermined time period to exhaust the gas inside the chamber 1 to the outside. As a result, the pressure inside the chamber 1 is reduced.

In the step S2, a process of making an organic solvent gas atmosphere in the chamber 1 is carried out. In the step S2, the processor 31 controls the supply operation for the organic solvent gas by the gas nozzles 13. More specifically, the processor 31 drives the organic solvent supply section 28 for a predetermined time period to supply an organic solvent vapor as an organic solvent gas to the gas supply pipe 22. In the step S2, the processor 31 controls the on/off valves 42 to a closed state and controls the on/off valves 43 to an opened state. The gas nozzles 13 discharge, into the chamber 1, the organic solvent vapor supplied to the gas supply pipe 22, thereby making an organic solvent vapor atmosphere in the chamber 1. In the step S2, the processor 31 drives the depressurization mechanism 26 for a predetermined time period to exhaust the gas inside the chamber 1 to the outside. As a result, the pressure inside the chamber 1 is reduced.

In the step S3, a process of pulling the substrate W out of the processing tank 3 is carried out. In the step S3, the processor 31 controls the movement mechanism 6 to cause the lifter 5 to move to the second position 5B. As a result, the substrate W is located outside the processing tank 3. In the step S3, the processor 31 drives the organic solvent supply section 28 for a predetermined time period to supply the organic solvent vapor to the gas supply pipe 22. In the step S3, the processor 31 controls the on/off valves 42 to a closed state, and controls the on/off valves 43 to an opened state. The gas nozzles 13 discharge, into the chamber 1, the organic solvent vapor supplied to the gas supply pipe 22, thereby making an organic solvent vapor atmosphere in the chamber 1. In the step S3, the processor 31 stops the driving of the depressurization mechanism 26.

In the step S4, a process of supplying the organic solvent gas toward an area including a contact position between the lifter 5 and the substrate W is carried out in a state in which the substrate W is pulled out of the processing tank 3. In the step S4, the processor 31 controls the movement mechanism 6 to continue the state in which the lifter 5 is located in the second position 5B. In the step S4, the processor 31 drives the organic solvent supply section 28 for a predetermined time period. Further, in the step S4, the processor 31 controls the on/off valves 42 and the on/off valves 43 to an opened state. This allows the gas nozzles 12 and the gas nozzles 13 to supply the organic solvent vapor into the chamber 1. That is, the gas nozzles 12 supply organic solvent vapor toward an area including the groove portions 622 and 632 of the side retaining arm 60 and the groove portions 722 and 732 of the center retaining arm 70.

In the step S4, the processor 31 stops the driving of the depressurization mechanism 26. Further, in the step S4, the processor 31 controls the on/off valve 41 to an opened state, and controls the on/off valve of the liquid drainage pipe 9 to an opened state. Thereby, the processing liquid inside the processing tank 3 is drained to the bottom portion of the chamber 1, and is then drained to the outside of the chamber 1 via the liquid drainage pipe 9.

In the step S5, a process of supplying an organic solvent gas toward an area including a contact position between the lifter 5 and the substrate W with the chamber 1 in a depressurized state, and continuing the supply for a predetermined time period is carried out. In the step S5, the processor 31 continues, from the step S4, the supply of the organic solvent vapor into the chamber 1 via the gas nozzles 12 and the gas nozzles 13. In the step S5, the processor 31 drives the depressurization mechanism 26 for a predetermined time period to exhaust the gas inside the chamber 1 to the outside. As a result, the pressure inside the chamber 1 is reduced. For example, in the step S5, the processor 31 continues, for a time period within a range of 3 seconds to 10 seconds, the supply of the organic solvent vapor toward the area including a contact position between the lifter 5 and the substrate W with the chamber 1 in a depressurized state. Further, the processor 31 continues, from the step S4, the process of draining the processing liquid inside the processing tank 3 to the outside of the chamber 1.

In the step S6, a process of supplying an inert gas as a drying gas toward the area including the contact position between the lifter 5 and the substrate W with the chamber 1 in a depressurized state, and continuing the supply for a predetermined time period is carried out. In the step S6, the processor 31 drives the gas supply section 29 for a predetermined time period. Further, in the step S6, the processor 31 controls the on/off valves 42 and the on/off valves 43 to an opened state. The gas nozzles 12 and the gas nozzles 13 discharge, into the chamber 1, the inert gas supplied to the gas supply pipe 22 to dry the substrate W. Further, in the step S6, the processor 31 continues the process of reducing the pressure inside the chamber 1 from the step S5. The steps S5 and S6 are each a process of drying the substrate W.

In the step S7, a process of setting the pressure inside the chamber 1 to the atmospheric pressure is carried out. In the step S7, the processor 31 drives the gas supply section 29. In the step S7, the processor 31 controls the on/off valves 42 and the on/off valves 43 to an opened state. This allows the gas nozzles 12 and the gas nozzles 13 to supply the inert gas into the chamber 1. In the step S7, the processor 31 stops the driving of the depressurization mechanism 26. As a result, the pressure inside the chamber 1 is set to the atmospheric pressure.

In the step S8, a process of transferring the substrate W to the outside of the chamber 1 is carried out. In the step S8, the processor 31 drives the gas supply section 29. In the step S8, the processor 31 controls the on/off valves 42 to a closed state and controls the on/off valves 43 to an opened state. In the step S8, the processor 31 controls the movement mechanism 6 to cause the lifter 5 to move to the third position 5C. This allows the substrate W to be transferred to the outside of the chamber 1 while supplying the inert gas into the chamber 1 from the gas nozzles 13.

Here, it has been known that, on a substrate that has undergone a drying process, peculiar particles adhere to the vicinities of portions supported by the support plates 62, 63, 72, and 73 of the lifter 5. The peculiar particles are detected as undesirable particles with the edge exclusion of the substrate W set to not more than 2 mm. That is, with the narrowing of the edge exclusion and the miniaturization of the structures formed on the substrate W, the acceptance criteria for the particles become stricter, and particles that were conventionally acceptable come to be detected as peculiar particles.

The inventors of the present invention considered that one cause of the adhesion of the peculiar particles to the substrate W is droplets of processing liquid remaining on the portions of the substrate W which come into contact with the support plates 62, 63, 72, and 73 of the lifter 5. For example, in some cases, after the substrate W has been taken out from the processing tank 3, droplets of DIW have remained on the portions of the substrate W which come into contact with the support plates 62, 63, 72, and 73. The following description will take as an example a case where the droplets of the processing liquid remain on the portions of the substrate W which come into contact with the inner support plate 62 and the outer support plate 63 of the side retaining arms 60.

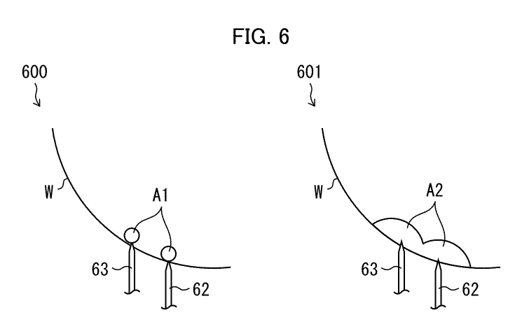

With reference to FIG. 6, the following will describe one cause of the adhesion of the peculiar particles to the substrate W. FIG. 6 is a view schematically illustrating one cause of the adhesion of the peculiar particles to the substrate W. The reference numeral 600 of FIG. 6 schematically illustrates the state of droplets A1 of DIW with the atmosphere inside the chamber 1 made an IPA atmosphere. The reference numeral 601 in FIG. 6 schematically illustrates the state of droplets A2 of DIW with the atmosphere inside the chamber 1 that has been made the IPA atmosphere changed to an N₂ gas atmosphere.

The reference numerals 600 and 601 of FIG. 6 respectively indicate droplets A1 and A2 of DIW which remain on portions of the substrate W which come into contact with the inner support plate 62 and the outer support plate 63 of the side retaining arms 60. The droplets A1 and A2 are droplets of DIW which remain on the substrate W when the substrate W that has been immersed in the processing tank 3 is taken out of the processing tank 3.

The state of the droplets A1 and A2 adhering to the substrate W is affected by differences in surface tension between the substrate W and the droplets A1 and A2, and between the atmosphere inside the chamber 1 and the droplets A1 and A2. As indicated by the reference numeral 600 of FIG. 6, in a case where the inside of the chamber 1 is in the IPA atmosphere, the droplets A1 in contact with the IPA atmosphere having a lower surface tension remain cohesive, without spreading. As indicated by reference numeral 601 of FIG. 6, in a case where the inside of the chamber 1 is changed from the IPA atmosphere to an N₂ gas atmosphere, the droplets A2 become liquid in which DIW and IPA are mixed. Accordingly, the droplets A2 that have been decreased in surface tension spread under the influence of the substrate W having a higher surface tension. In particular, for example, in a case where the surface of the substrate W is hydrophilic, such as a case where a silicon oxide film is formed on the surface of the substrate W, the droplets A2 likely spread.

There has been a possibility that the droplets A1 and A2 contain particles. In a case where the droplets A1 and A2 contain the particles, generation of a convection current in the droplets A1 and A2 causes the particles in the droplets A1 and A2 to move in the droplets A1 and A2 due to the convection current. The convection current in the droplets A1 and A2 is generated, for example, in a case where the drying process of drying the substrate W is carried out. On the surface of the substrate W undergoing the drying process, the surface tension increases because of the temperature on the surface of the substrate W due to the evaporation of the liquid. Therefore, in the droplets A1 and A2 on the substrate W undergoing the drying process, convection currents directed from the top sides of the central portions of the outer profiles of the droplets A1 and A2 toward the substrate W side are generated. When such convection currents from the tops toward the substrate W are generated, the convection currents are directed, in the vicinity of the substrate W, along the surface of the substrate W toward outer peripheral edge portion sides of the outer profiles of the droplets A1 and A2. The droplets A1 and A2 on the substrate W undergoing the drying process gradually evaporate from the central portions of the outer profiles of the droplets A1 and A2, and finally, the outer peripheral edge portions of the outer profiles of the droplets A1 and A2 evaporate. That is, it has been considered that in a case where the droplets A1 and A2 contain the particles, the particles adhere to the substrate W along the outer profiles of the droplets A1 and A2 after the droplets A1 and A2 on the substrate W have evaporated.

It has been considered that the fact that the droplets A1 indicated by the reference numeral 600 of FIG. 6 remain cohesive without spreading makes it possible to, even if the droplets A1 dry and the particles adhere to the substrate W, narrow the range of the adhesion of the particles. However, it has been considered that the droplets A2 indicated by the reference numeral 601 of FIG. 6 have spread, and thus the drying of the droplets A2 results in a broader range of the particles adhering to the substrate W. Therefore, it has been considered that it is possible to reduce the possibility that peculiar particles adhere to the substrate W by, after carrying out a process of replacing the processing liquid with organic solvent gas, carrying out a process of drying the substrate W under an atmosphere of the organic solvent gas, and thereafter carrying out another drying process of drying the substrate W under an atmosphere of a drying gas.

According to the substrate processing apparatus 100 described above, with the chamber 1 in a depressurized state, an organic solvent gas is supplied toward an area including a contact position between the lifter 5 and the substrate W for a predetermined time period. Therefore, even if droplets of the processing liquid remain on a portion of the substrate W in the vicinity of the contact position with the lifter 5, it is possible to make the droplets less likely to spread, while proceeding with the drying of the substrate W. Therefore, it is possible to reduce the possibility that the peculiar particles adhere to the substrate W. This makes it possible to improve a yield of the product. In particular, the invention of the present application is effective to the substrate W having a hydrophilic surface, such as one having a surface on which a silicon oxide film is formed.

Moreover, by continuing the supply of the organic solvent gas with the chamber 1 in a depressurized state for a period within a range of 3 seconds to 10 seconds, it is possible to proceed with the drying of the substrate W while reducing the spreading of the droplets of the processing liquid adhering to the substrate W. Furthermore, since the supply time for the organic solvent gas can be limited, it is possible to reduce the work amount for the substrate processing by the substrate processing apparatus 100.

By disposing the gas nozzles 12 at a height lower than the height of the center C1 of the substrate W retained by the lifter 5 located in the second position 5B, the organic solvent gas supplied from the gas nozzles 12 can be more efficiently supplied to an area including a contact position between the lifter 5 and the substrate W. This makes it possible to reduce the possibility that the peculiar particles adhere to the substrate W.

With respect to gas supply in the chamber 1, instead of switching between the organic solvent vapor and the inert gas in the gas supply pipe 22, a configuration may be employed which includes a gas supply pipe 22A for supplying only inert gas and a gas supply pipe 22B for supplying only organic solvent vapor, in which gas nozzles 12A and 12B corresponding to the pipes are disposed instead of the gas nozzles 12, and in which gas nozzles 13A and 13B are similarly disposed instead of the gas nozzles 13.

Aspects of the present invention can also be expressed as follows:
A substrate processing apparatus in accordance with an aspect of the present disclosure is a substrate processing apparatus configured to carry out a predetermined process on a substrate, the substrate processing apparatus including: a processing tank storing a processing liquid; a chamber accommodating the processing tank; a lifter retaining the substrate; a movement mechanism configured to raise and lower the lifter between a first position where the substrate is immersed in the processing liquid inside the processing tank and a second position where the substrate is located outside the processing tank; a processing liquid nozzle configured to supply a processing liquid to the processing tank; a gas nozzle configured to supply an inert gas or organic solvent gas into the chamber; a control section configured to control an operation by the movement mechanism and control a supply operation for a processing liquid by the processing liquid nozzle, a supply operation for the inert gas by the gas nozzle, and a supply operation for the organic solvent gas by the gas nozzle; and a memory storing information indicating a control operation of the control section, wherein in cooperation with the memory, the control section carries out control to (i) immerse the substrate in the processing liquid stored in the processing tank, (ii) make an atmosphere of the organic solvent gas in the chamber, (iii) supply the organic solvent gas toward an area including a contact position between the lifter and the substrate in a state in which the substrate is pulled out of the processing tank, and (iv) supply the organic solvent gas toward the area including the contact position between the lifter and the substrate with the chamber in a depressurized state and continue the supply for a predetermined time period.

Further, in a substrate processing apparatus in accordance with an aspect of the present disclosure, the control section continues, within a range of 3 seconds to 10 seconds, the supply of the organic solvent gas toward the area including the contact position between the lifter and the substrate with the chamber in the depressurized state.

Further, in a substrate processing apparatus in accordance with an aspect of the present disclosure, the gas nozzle is disposed in a position lower than a height of the center of the substrate retained by the lifter located in the second position.

A substrate processing method in accordance with an aspect of the present disclosure is a substrate processing method for a substrate processing apparatus configured to carry out a predetermined process on a substrate, the substrate processing apparatus including a processing tank storing a processing liquid, a chamber accommodating the processing tank, a lifter retaining the substrate, a movement mechanism configured to raise and lower the lifter between a first position where the substrate is immersed in the processing liquid inside the processing tank and a second position where the substrate is located outside the processing tank, a processing liquid nozzle configured to supply a processing liquid to the processing tank, and a gas nozzle configured to supply an inert gas or organic solvent gas into the chamber, the substrate processing method comprising: (i) immersing the substrate in the processing liquid stored in the processing tank; (ii) making an atmosphere of the organic solvent gas in the chamber; (iii) supplying the organic solvent gas toward an area including a contact position between the lifter and the substrate in a state in which the substrate is pulled out of the processing tank; and (iv) supplying the organic solvent gas toward the area including the contact position between the lifter and the substrate with the chamber in a depressurized state and continuing the supplying for a predetermined time period.

### REFERENCE SIGNS LIST

1 Chamber

3 Processing tank

5 Lifter

5A First position

5B Second position

6 Movement mechanism

11 Processing liquid nozzle

12 Gas nozzle (inert gas nozzle, organic solvent nozzle)

13 Gas nozzle

31 Processor (control section)

32 Memory

100 Substrate processing apparatus

C1 Center

1. A substrate processing apparatus configured to carry out a predetermined process on a substrate, the substrate processing apparatus comprising:
a processing tank storing a processing liquid;
a chamber accommodating the processing tank;
a lifter retaining the substrate;
a movement mechanism configured to raise and lower the lifter between a first position where the substrate is immersed in the processing liquid inside the processing tank and a second position where the substrate is located outside the processing tank;
a processing liquid nozzle configured to supply a processing liquid to the processing tank;
a gas nozzle configured to supply an inert gas or organic solvent gas into the chamber;
a control section configured to control an operation by the movement mechanism and control a supply operation for a processing liquid by the processing liquid nozzle, a supply operation for the inert gas by the gas nozzle, and a supply operation for the organic solvent gas by the gas nozzle; and
a memory storing information indicating a control operation of the control section, wherein
in cooperation with the memory, the control section carries out control to
(i) immerse the substrate in the processing liquid stored in the processing tank,
(ii) make an atmosphere of the organic solvent gas in the chamber,
(iii) supply the organic solvent gas toward an area including a contact position between the lifter and the substrate in a state in which the substrate is pulled out of the processing tank, and
(iv) supply the organic solvent gas toward the area including the contact position between the lifter and the substrate with the chamber in a depressurized state and continue the supply for a predetermined time period.

2. The substrate processing apparatus according to claim 1, wherein the control section continues, within a range of 3 seconds to 10 seconds, the supply of the organic solvent gas toward the area including the contact position between the lifter and the substrate with the chamber in the depressurized state.

3. The substrate processing apparatus according to claim 1, wherein the gas nozzle is disposed in a position lower than a height of the center of the substrate retained by the lifter located in the second position.

4. A substrate processing method for a substrate processing apparatus configured to carry out a predetermined process on a substrate,
the substrate processing apparatus including
a processing tank storing a processing liquid,
a chamber accommodating the processing tank,
a lifter retaining the substrate,
a movement mechanism configured to raise and lower the lifter between a first position where the substrate is immersed in the processing liquid inside the processing tank and a second position where the substrate is located outside the processing tank,
a processing liquid nozzle configured to supply a processing liquid to the processing tank, and
a gas nozzle configured to supply an inert gas or organic solvent gas into the chamber,
the substrate processing method comprising:
(i) immersing the substrate in the processing liquid stored in the processing tank;
(ii) making an atmosphere of the organic solvent gas in the chamber;
(iii) supplying the organic solvent gas toward an area including a contact position between the lifter and the substrate in a state in which the substrate is pulled out of the processing tank; and
(iv) supplying the organic solvent gas toward the area including the contact position between the lifter and the substrate with the chamber in a depressurized state and continuing the supplying for a predetermined time period.
